(19) United States
(12) Patent Application Publication
(10) Pub. No.: US 2022/0171100 A1
(43) Pub. Date: Jun. 2, 2022

(54) DECORATIVE FILM, WINDOW FILM AND LAMINATE HAVING THE SAME, AND METHOD FOR MANUFACTURING THE SAME

(71) Applicant: DONGWOO FINE-CHEM CO., LTD., Iksan-si, Jeollabuk-do (KR)

(72) Inventors: Duckkyeom KIM, Hwaseong-si (KR); Kyoung Mo LEE, Pyeongtaek-si (KR); Tae Hyung LEE, Hwaseong-si (KR)

(73) Assignee: DONGWOO FINE-CHEM CO., LTD., Iksan-si, Jeollabuk-do (KR)

(21) Appl. No.: 17/599,296

(22) PCT Filed: Mar. 23, 2020
(86) PCT No.: PCT/KR2020/003935

§ 371 Date: Sep. 28, 2021

(30) Foreign Application Priority Data
Mar. 29, 2019 (KR) 10-2019-0036756
Feb. 11, 2020 (KR) 10-2020-0016354

(51) Int. Cl. G02B 1/14; G03F 7/00; G03F 7/004; G03F 7/16

(52) U.S. Cl. CPC G02B 1/14; G03F 7/0007; H01Q 1/22; G03F 7/168; G03F 7/0045

(57) ABSTRACT

A decorative film includes a protective layer composed of an organic film, and a black matrix patterned on a front surface of the protective layer, composed of a single-layer organic film, and having a single-step tapered portion at a boundary with a display area.

### TECHNICAL FIELD

The present invention relates to a decorative film, and specifically, to a decorative film having a black matrix, a window film and a laminate having the same, and a manufacturing method thereof.

### BACKGROUND ART

A decorative film performs a decorative function while blocking light, and it is widely used in a device or material that can include a decorative film, for example, flexible display windows (ultra-thin glass windows, film windows, etc.), interlayer films (shock absorbing layers, scattering prevention layers, etc.), touch sensors, and polarizing layers, and the like.

A decorative film may be used for a touch sensor. The touch sensor includes a central display area (view area) which consists of sensing cells and through which light is transmitted, and a marginal bezel area where wiring is arranged and light is blocked. The decorative film can be attached to the bezel area. The decorative film may include a black matrix that blocks light.

As a prior art in which a decorative film is used in the touch sensor, there is Korea Patent Publication No. 2018-0107347 (Decorative film integrated touch sensor and manufacturing method thereof). In this prior art, it includes a silver nanofiber layer covering a lower surface of the decorative film part, and a transparent electrode of the touch sensor is formed on the silver nanofiber layer. Through this structure, Korean Patent Publication No. 2018-0107347 can omit a UV glue layer for removing a step difference of a black matrix.

However, the decorative film of the prior art applied to the touch sensor is still thick due to the step difference of the black matrix and the large thickness of the silver nanofiber layer, and light leakage at the boundary between the display area and the black matrix area may occur.

### DISCLOSURE OF INVENTION

### Technical Problem

The present invention is to solve the above problems of the prior art and intends to provide a decorative film capable of further reducing the thickness of the decorative film by minimizing the thickness of a black matrix and minimizing light leakage at the boundary between a display area and the black matrix.

### Technical Solution

A decorative film of the present invention for achieving this purpose may include a protective layer, a black matrix, and the like.

The protective layer may be composed of an organic film.

The black matrix may be patterned on a front surface of the protective layer. The black matrix may be composed of a single-layer organic film, and may have a single-step tapered portion at a boundary with a display area.

The decorative film of the present invention may further include a separation layer.

The separation layer may be coupled to a lower portion of the protective layer and composed of an organic film.

The decorative film of the present invention may further include a planarization layer formed on front surfaces of the protective layer and the black matrix and composed of a transparent organic film.

In the decorative film of the present invention, the planarization layer may be composed of an overcoating layer and may have a thickness of 1 to 2.5 μm.

The decorative film of the present invention may further include an adhesive layer. The adhesive layer may be formed on front surfaces of the protective layer and the black matrix and composed to have a thickness of 1 to 50 μm.

In the decorative film of the present invention, the black matrix may have a slope formed within a line width range of 0.5 to 2 μm from the display area.

In the decorative film of the present invention, the black matrix may have a uniform thickness in an area after the slope.

In the decorative film of the present invention, the black matrix may have a thickness of 1.2 to 2.0 μm and an optical density of 5 or more in the area after the slope.

A window film of the present invention may comprise the decorative film described above, a bonding layer coupled to a rear surface of the separation layer, and a functional layer coupled to the bonding layer.

In the window film of the present invention, the functional layer may be a transparent film, a polarizing plate, a touch sensor layer, a moisture-proof film, or an ultra-thin glass. Here, the ultra-thin glass may have a thickness of 25 to 50 μm.

In the window film of the present invention, the transparent film may be at least one selected from the group consisting of polyethyleneetherphthalate, polyethylenenaphthalate, polycarbonate, polyarylate, polyetherimide, polyethersulfonate, polyimide, polyethertherketone, polyethylene terephthalate, triacetyl cellulose, cyclo-olefin polymer, aramide, FRP, polyurethane, polyacrylate and polydimethylsiloxane.

In the window film of the present invention, the transparent film may be composed of, in particular, polyethylene terephthalate, colorless polyimide, a laminate of polyethylene terephthalate and colorless polyimide, or colorless polyimide including a hard coating.

A window laminate of the present invention may comprise the window film described above, and a touch sensor or an antenna laminated on the window film.

A method for manufacturing a decorative film according to the present invention may comprise steps of forming a separation layer composed of an organic film on a front surface of a carrier substrate, forming a protective layer composed of an organic film on a front surface of the separation layer, coating a photosensitive black resin composition on a front surface of the protective layer, exposing and developing the photosensitive black resin composition to form a black matrix having a single layer and a single step, post-baking the black matrix, and separating the separation layer and the carrier substrate from the protective layer to form the decorative film.

Another method for manufacturing a decorative film according to the present invention may comprise steps of forming a separation layer composed of an organic film on a front surface of a carrier substrate, forming a protective layer composed of an organic film on a front surface of the separation layer, coating a photosensitive black resin composition on a front surface of the protective layer, exposing and developing the photosensitive black resin composition to form a black matrix having a single layer and a single step, post-baking the black matrix, and separating the carrier substrate from the separation layer to form the decorative film.

The method for manufacturing a decorative film according to the present invention may further comprise a step of forming an overcoating planarization layer composed of a transparent organic film on front surfaces of the protective layer and the black matrix.

In the method for manufacturing a decorative film according to the present invention, the planarization layer may be formed with a photolithography process.

The method for manufacturing a decorative film according to the present invention may further comprise a step of forming an adhesive layer on front surfaces of the protective layer and the black matrix.

In the method for manufacturing a decorative film according to the present invention, the post-baking may be a heat treatment at 190 to 250° C. for 10 to 30 minutes.

### Advantageous Effects

According to the decorative film of the present invention having such a configuration, the thickness of the black matrix can be minimized to 2.0 μm or less by configuring the black matrix to have a single layer and a single step through a photolithography process, through which it is possible to reduce the thickness of the planarization layer laminated on top of the black matrix, and as a result, it is possible to significantly reduce the overall thickness of the decorative film.

In addition, according to the decorative film of the present invention, light leakage at the boundary between the display area and the black matrix area can be minimized by setting the black matrix to have an optical density of 5 or more from a point spaced apart from the display area by at least 2 μm.

### DESCRIPTION OF DRAWINGS

FIG. 1 is a cross-sectional view of a decorative film of the first embodiment according to the present invention.

FIG. 2 is an enlarged photograph showing a shape of a black matrix in a decorative film of the first embodiment according to the present invention.

FIG. 3 is a cross-sectional view of a decorative film of the second embodiment according to the present invention.

FIG. 4 is a manufacturing process diagram of a decorative film according to the present invention.

### BEST MODE

Hereinafter, the present invention will be described in detail with reference to the accompanying drawings.

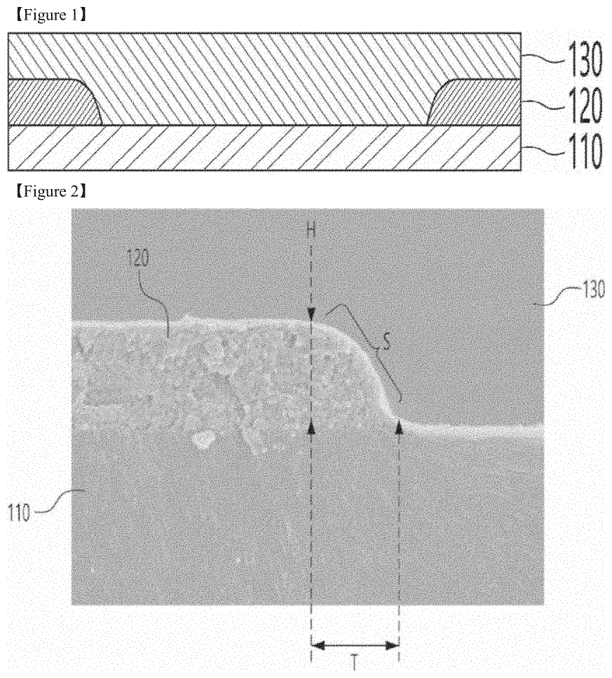

FIG. 1 is a cross-sectional view of a decorative film of the first embodiment according to the present invention.

As shown in FIG. 1, the decorative film of the first embodiment may be configured to include a protective layer 110, a black matrix 120, a planarization layer 130, and so on.

The protective layer 110 may prevent contamination of the black matrix 120 and prevent damage to the black matrix 120 when the protective layer 110 is separated from a separation layer 140 and a carrier substrate 200 in the manufacturing process.

The protective layer 110 may be formed of an organic layer including a polymer having at least one of a hydroxyl group, a carboxyl group, and an amide group.

The black matrix 120 is patterned on a front surface of the protective layer 110 to function as a light blocking layer that blocks light. The black matrix 120 may be located in a non-display area of a display device, that is, a bezel area surrounding a display area.

The black matrix 120 may be formed as a single layer of a thin film. The black matrix 120 may have a tapered portion having a single step difference.

The black matrix 120 may be formed of a black resin composition. As the black resin composition, a composition including a resin in which black pigment particles are dispersed, a binder resin, a polymerizable compound, a polymerization initiator, and an additive, or a photocurable (thermosetting) resin composition having black color by including a black pigment may be used. For the black matrix 120, a composition capable of selective patterning and having an optical density of 3.8 or more per 1 μm may be used.

The black pigment may be carbon black, graphite, metal oxide, or the like. The black pigment may include an organic black pigment, and the organic black pigment may be aniline black, lactam black, or perylene black series.

The additive may include an adhesion promoter, a photocrosslinking sensitizer, a curing accelerator, a surfactant, a dispersant, an antioxidant, an ultraviolet absorber, a thermal polymerization inhibitor, a leveling agent, and the like, and may include one or more among them.

The black matrix 120 may be formed by a photolithography process to form a thin film. In the photolithography process, a photosensitive black resin composition is applied on the protective layer 110 and the photosensitive black resin composition is then exposed to light and developed. As an exposure light source, a mercury vapor arc, carbon arc, Xe arc, etc. that emits light having a wavelength of 250 to 450 nm may be used.

The planarization layer 130 is formed on front surfaces of the protective layer 110 and the black matrix 120, and may perform functions such as correcting a surface step difference of the black matrix 120, planarization, refractive index control, and protection.

The planarization layer 130 may be formed of an organic film, or may be formed of an inorganic film or an organic-inorganic hybrid film. As the organic film, polyacrylate, polyimide, polyester, or the like may be used. As the inorganic film, silazane, silica, or an inorganic film or metal film having light transmittance secured may be used. The inorganic film may contain inorganic fillers. The inorganic fillers may be spherical nanoparticles capable of improving light extraction efficiency. The organic-inorganic hybrid film may use a dispersed organic-inorganic hybrid composite such as siloxane or silsesquioxane.

The planarization layer 130 may be configured as an overcoating layer. In this case, the planarization layer 130 may have a thickness of 1 to 2.5 μm.

In FIG. 1, the overcoating planarization layer 130 may be replaced with an adhesive layer or a bonding layer, in which the adhesive layer may be formed using a pressure sensitive adhesive (PSA) composition or an optically clear adhesive (OCA) composition. For example, the pressure-sensitive adhesive layer may be formed from an adhesive composition including an acrylic copolymer and a crosslinking agent, or may be formed from an adhesive composition including a urethane (meth)acrylate resin, a (meth)acrylate ester monomer and a photoinitiator. The adhesive layer may have a thickness of 1 to 50 μm.

FIG. 2 is an enlarged photograph showing a shape of a black matrix in a decorative film of the first embodiment according to the present invention.

As shown in FIG. 2, the black matrix 120 may be configured as a single layer of a thin film through a photolithography process. The black matrix 120 may be formed of an organic material having an optical density of 3.8 or more per 1 μm in thickness, for example, a photosensitive black resin composition. It is preferable to configure the black matrix 120 to have the optical density of 5.0 or more. For this purpose, the thickness H may be configured to be 1.0 to 2.0 μm, preferably 1.2 to 2.0 μm.

The black matrix 120 may have a tapered portion having a single step difference. The tapered portion may have a slope S. The slope S may be formed in the photolithography process. The tapered portion may have a tail at the lower side, and the tail may be formed in a post-bake process. The post-bake process may be performed at 190 to 250° C. for 10 to 30 minutes.

In the black matrix 120, the width T of the tapered portion, that is, the width from the display area to the point with the maximum thickness H of the black matrix 120 may be within 2 μm. The black matrix 120 may have the optical density of 5 or more, preferably 6 or more, and the thickness H of, for example, 1.2 to 2.0 μm, from the point spaced 2 μm apart from the display area.

In the black matrix 120, it may be desirable to secure the optical density of 3.0 or more after 0.5 μm from the display area.

The black matrix 120 may form the slope S within a width range of 0.5 to 2 μm from the display area. The black matrix 120 may have a uniform thickness in the area after the slope S.

Through this configuration, the black matrix 120 may minimize light leakage at the boundary of the display area.

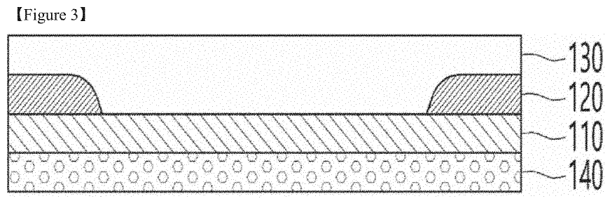

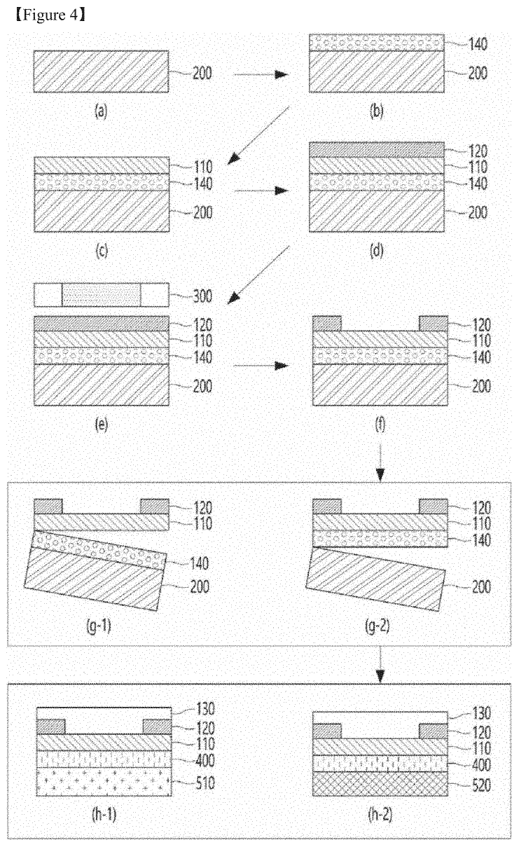

FIG. 3 is a cross-sectional view of a decorative film of the second embodiment according to the present invention.

As shown in FIG. 3, the decorative film of the second embodiment may be configured to further include a separation layer 140 under a protective layer 110.

The separation layer 140 supports and protects the protective layer 110 and the black matrix 120 formed on the front surface, and may be separated from the protective layer 110 or a carrier substrate 200 in a manufacturing process.

The separation layer 140 may have a peeling strength of 5 N/25 mm or less, preferably 1 N/25 mm, with respect to the carrier substrate 200, for example, a glass substrate, and the surface energy after peeling may be 30 to 70 mN/m. The separation layer 140 may have a thickness of 10 to 1000 nm, preferably 50 to 500 nm.

The peeling strength of the separation layer 140 with respect to the protective layer 110 may be, for example, 8N/25 mm or more and 15N/25 mm or less, and preferably 10N/25 mm or more.

The separation layer 140 may be composed of an organic polymer film, and the organic polymer film includes a polyimide-based polymer, polyvinyl alcohol-based polymer, polyamic acid-based polymer, polyamide-based polymer, polyethylene-based polymer, polystyrene-based polymer, polynorbornene-based polymer, phenylmaleimide copolymer-based polymer, polyazobenzene-based polymer, polyphenylenephthalamide-based polymer, polyester-based polymer, polymethyl methacrylate-based polymer, polyarylate-based polymer, cinnamate-based polymer, coumarin-based polymer, phthalimidine-based polymer, chalcone-based polymer, aromatic acetylene-based polymer, and the like.

FIG. 4 is a manufacturing process diagram of a decorative film according to the present invention.

First, in (a) of FIG. 4, a glass substrate 200 may be prepared for the decorative film of the present invention. The glass substrate 200 is a carrier substrate, which may be of any material as long as it has an appropriate strength to be fixed without being easily bent or distorted during the process. For example, quartz, silicon wafer, sus, etc. may be used in addition to glass.

In (b) of FIG. 4, a separation layer 140 made of an organic film may be formed on the front surface of the glass substrate 200.

The separation layer 140 may be formed by a slit coating method, knife coating method, spin coating method, casting method, micro gravure coating method, gravure coating method, bar coating method, roll coating method, wire bar coating method, dip coating method, spray coating method, screen printing method, gravure printing method, flexographic printing method, offset printing method, inkjet coating method, dispenser printing method, nozzle coating method, capillary coating method, or the like.

In (c) of FIG. 4, a protective layer 110 may be formed on the front surface of the separation layer 140. The protective layer may be formed by coating/curing, vapor deposition, etc. of a composition for forming the protective layer including a polymer having at least one of a hydroxyl group, a carboxyl group, and an amide group.

In (d) of FIG. 4, a photosensitive black resin composition 120 may be coated on the front surface of the protective layer 110. As the photosensitive black resin composition 120, a composition including a resin in which black pigment particles are dispersed, a binder resin, a polymerizable compound, a polymerization initiator, an additive, and the like may be used. A composition capable of selective patterning having an optical density of at least 3.8 per μm may be desirable.

The photosensitive black resin composition 120 may be formed to have a thickness of 1.0 to 2.0 μm, preferably 1.2 to 2.0 μm.

The photosensitive black resin composition 120 may be formed by a slit coating method, knife coating method, spin coating method, casting method, micro gravure coating method, gravure coating method, bar coating method, roll coating method, wire bar coating method, dip coating method, spray coating method, or the like.

In (e) of FIG. 4, the photosensitive black resin composition 120 may be exposed to light using a photomask 300. As the exposure light, visible light, ultraviolet light, X-ray, electron beam, etc. may be used. A pre-bake may be additionally performed prior to exposure.

Through development after exposure, a pattern of the black matrix may be formed. The development may be performed using, for example, a 90 to 100-fold dilution of an aqueous alkali solution containing 1 to 5 wt % of a carbonate such as sodium carbonate, potassium carbonate, lithium carbonate, etc., with a developer, an ultrasonic cleaner, and the like at a temperature of 10 to 50° C.

As shown in (f) of FIG. 4, the patterned photosensitive black resin composition 120 may form the black matrix composed of a single layer and having a tapered portion of a single step.

In (f) of FIG. 4, the patterned photosensitive black resin composition 120 may be subjected to post-bake. The post-bake step may be performed at 190 to 250° C. for 10 to 30 minutes. The tail of the tapered portion may be adjusted by a heat treatment process in the photolithography process, and the shape may be adjusted to form other layers positioned on the black matrix, for example, an overcoating planarization layer, TSP wiring, antenna wiring, and the like. The post-bake may be performed by heating on a hot plate, in an oven, or by irradiating infrared rays, or by using a convection oven.

In (g-1) of FIG. 4, by separating the separation layer 140 and the glass substrate 200 from the protective layer 110, it is possible to form the decorative film 110 and 120 of the first embodiment.

Alternatively, as shown in (g-2) of FIG. 4, by separating the glass substrate 200 from the separation layer 140, it is possible to form the decorative film 140, 110, and 120 of the second embodiment including the separation layer 140.

In (h-1) and (h-2) of FIG. 4, the decorative film of the first embodiment may combine the planarization layer 130 on the front surface and the functional layers 510 and 520 via the adhesive layer 400 on the rear surface.

The planarization layer 130 may be composed of an overcoating layer using an organic film such as polyacrylate, polyimide, or polyester. In this case, the planarization layer 130 may be formed to have a thickness of 1.5 to 2.5 μm. The planarization layer 130 may be formed of an adhesive layer or a bonding layer. In this case, the planarization layer 130 may have a thickness of 1 to 50 m.

In (h-1) and (h-2) of FIG. 4, the planarization layer 130 may be formed by a photolithography process for both the overcoat layer and the adhesive layer to form a thin film. Of course, it is not excluded to form the planarization layer 130 with photocuring, thermosetting, or photocuring and thermosetting at the same time.

In (h-1) and (h-2) of FIG. 4, a thermosetting or photocurable adhesive such as polyester-based, polyether-based, urethane-based, epoxy-based, silicone-based, or acrylic-based may be used for the adhesive layer 400.

The functional layers 510 and 520 may include a transparent film, a polarizing plate, a moisture-proof film, a touch sensor layer, an ultra-thin glass, or the like. The functional layer may be a layer composed of polyethylene terephthalate, colorless polyimide, a laminate of polyethylene terephthalate and colorless polyimide, colorless polyimide including a hard coating, or the like.

The transparent film may be made of, for example, at least one selected from the group consisting of polyethyleneetherphthalate, polyethylenenaphthalate, polycarbonate, polyarylate, polyetherimide, polyethersulfonate, polyimide, polyethertherketone, polyethylene terephthalate, triacetyl cellulose, cyclo-olefin polymer, aramide, FRP, polyurethane, polyacrylate and polydimethylsiloxane.

A window laminate according to the present invention may be composed of a decorative film including the functional layer described above, that is, a window film, and a touch sensor, an antenna, and the like laminated on the window film.

The decorative film of the present invention described above can be applied to various display devices including a bezel pattern. The display device includes a plasma display panel (PDP), light emitting diode (LED), organic light emitting diode (OLED), liquid crystal display (LCD), and thin film transistor liquid crystal display (LCD-TFT), and the like.

In the above, the present invention has been described through various embodiments, which are intended to illustrate the present invention. Those skilled in the art will be able to modify or revise these embodiments in other forms. However, since the scope of the present invention is defined by the claims below, it can be interpreted that such modifications or revisions are included in the scope of the present invention.

[Description of reference numerals]

| | |
|---|---|
| 110: protective layer | 120: black matrix |
| 130: planarization layer | 140: separation layer |
| 200: glass substrate | 300: photo mask |
| 400: adhesive layer | 510: hard-coated colorless PI film |
| 520: PET film | S: slope |
| T: width of tapered portion | H: maximum thickness of tapered portion |

1. A decorative film comprising:
a protective layer composed of an organic film; and
a black matrix patterned on a front surface of the protective layer, composed of a single-layer organic film, and having a single-step tapered portion at a boundary with a display area.

2. The decorative film according to claim 1, further comprising a separation layer coupled to a lower portion of the protective layer and composed of an organic film.

3. The decorative film according to claim 1, further comprising a planarization layer formed on front surfaces of the protective layer and the black matrix and composed of a transparent organic film.

4. The decorative film according to claim 3, wherein the planarization layer is composed of an overcoating layer and has a thickness of 1 to 2.5 μm.

5. The decorative film according to claim 1, further comprising an adhesive layer formed on front surfaces of the protective layer and the black matrix and having a thickness of 1 to 50 μm.

6. The decorative film according to claim 1, wherein the black matrix has a slope formed within a width range of 0.5 to 2 μm from the display area.

7. The decorative film according to claim 6, wherein the black matrix has a uniform thickness in an area after the slope.

8. The decorative film according to claim 7, wherein the black matrix has a thickness of 1.2 to 2.0 μm and an optical density of 5 or more in the area after the slope.

9. A window film comprising:
the decorative film according to claim 1;
a bonding layer coupled to a rear surface of the protective layer; and
a functional layer coupled to the bonding layer.

10. The window film according to claim 9, wherein the functional layer is a transparent film, a polarizing plate, a touch sensor layer, a moisture-proof film, or an ultra-thin glass.

11. The window film according to claim 10, wherein the transparent film includes at least one selected from the group consisting of polyethyleneetherphthalate, polyethylenenaphthalate, polycarbonate, polyarylate, polyetherimide, polyethersulfonate, polyimide, polyethertherketone, polyethylene terephthalate, triacetyl cellulose, cyclo-olefin polymer, aramide, FRP, polyurethane, polyacrylate and polydimethylsiloxane.

12. The window film according to claim 11, wherein the transparent film is composed of polyethylene terephthalate, colorless polyimide, a laminate of polyethylene terephthalate and colorless polyimide, or colorless polyimide including a hard coating.

13. A window laminate comprising:
the window film according to claim 9; and
a touch sensor or an antenna laminated on the window film.

14.-19. (canceled)

20. A window film comprising:
the decorative film according to claim 2;
a bonding layer coupled to a rear surface of the separation layer; and
a functional layer coupled to the bonding layer.

21. The window film according to claim 20, wherein the functional layer is a transparent film, a polarizing plate, a touch sensor layer, a moisture-proof film, or an ultra-thin glass.

22. The window film according to claim 21, wherein the transparent film includes at least one selected from the group consisting of polyethyleneetherphthalate, polyethylenenaphthalate, polycarbonate, polyarylate, polyetherimide, polyethersulfonate, polyimide, polyethertherketone, polyethylene terephthalate, triacetyl cellulose, cyclo-olefin polymer, aramide, FRP, polyurethane, polyacrylate and polydimethylsiloxane.

23. The window film according to claim 22, wherein the transparent film is composed of polyethylene terephthalate, colorless polyimide, a laminate of polyethylene terephthalate and colorless polyimide, or colorless polyimide including a hard coating.

24. A window laminate comprising:
the window film according to claim 20; and
a touch sensor or an antenna laminated on the window film.
